(19) United States
(12) Patent Application Publication
(10) Pub. No.: US 2024/0333426 A1
(43) Pub. Date: Oct. 3, 2024

(54) METHOD AND SYSTEM FOR PHYSICAL LAYER JOINT ERROR CORRECTION CODING OF MULTIPLE PAYLOADS

(71) Applicant: Huawei Technologies Co., Ltd., Shenzhen (CN)

(72) Inventors: Huazi Zhang, Kanata (CA); Jianglei Ma, Ottawa (CA); Wen Tong, Ottawa (CA)

(21) Appl. No.: 18/743,680

(22) Filed: Jun. 14, 2024

Related U.S. Application Data
(63) Continuation of application No. PCT/CN2021/138883, filed on Dec. 16, 2021.

(51) Int. Cl. H04L 1/00; H03M 13/13; H03M 13/25

(52) U.S. Cl. CPC H04L 1/0061; H03M 13/13; H03M 13/255

(57) ABSTRACT

Systems and methods are provided that deliver unequal error protection for multiple payloads in a single forward error correction codeword at the air interface layer of wireless communication networks. To simultaneously solve the two problems of (i) providing differential treatment for high and low priority payloads (e.g. higher QoS for payload with higher priority), and (ii) enhancing the overall coding gain, a joint coding scheme is provided in which a high-priority payload is combined with a low priority payload, and a combined payload is jointly encoded to generate a single long codeword. For example, one or more small URLLC messages (e.g. from sensors) can be combined with a video payload or an eMBB payload.

### CROSS-REFERENCE TO RELATED APPLICATIONS

This application is a continuation of International Application No. PCT/CN2021/138883, filed on Dec. 16, 2021, and entitled “METHOD AND SYSTEM FOR PHYSICAL LAYER JOINT ERROR CORRECTION CODING OF MULTIPLE PAYLOADS,” the disclosure of which is hereby incorporated by reference in its entirety.

### TECHNICAL FIELD

The application relates to error correction coding, such as for use in wireless communications systems.

### BACKGROUND

Wireless communication systems of the future, such as sixth generation or “6G” cellular communications, will trend toward ever-diversified application scenarios. Even a single device will generate different types of packets. These packets usually have different packet sizes, different quality of service (QOS) requirements, and different traffic patterns. Therefore, new air interface designs and protocols are needed to handle this diversity in 6G.

Channel coding is a component of the air interface that provides encoding and decoding schemes for error correction. The coding gain of a given scheme depends heavily on code length and code rates. Longer codes and lower code rates typically lead to better error correction performance. In existing channel coding schemes, code lengths and code rates are adaptively adjusted according to current channel states, based on channel quality indication (CQI) feedback and scheduling algorithms.

### SUMMARY

Systems and methods are provided that can be used to deliver unequal error protection, or unequal latency, for multiple payloads in a single forward error correction codeword at the air interface layer of wireless communication networks. To simultaneously solve the two problems of (i) providing differential treatment for high and low priority payloads (e.g. higher QoS for payload with higher priority), and (ii) enhancing the overall coding gain, a joint coding scheme is provided in which a high-priority payload is combined with a low priority payload, and a combined payload is jointly encoded to generate a single longer codeword. For example, one or more small ultra-reliable low latency communication (URLLC) messages (e.g. from sensors) can be combined with a video payload or an enhanced mobile broadband (eMBB) payload. The use of a single larger payload results in longer codeword length, which improves overall error protection. Early termination for the high priority payload may be possible, improving latency and decoding efficiency.

According to one aspect of the present disclosure, there is provided a method for an encoding apparatus. The method involves obtaining a first set of payload bits having a first priority and a second set of payload bits having a second priority lower than said first priority. An input bit sequence is encoded using an error correction code to produce a codeword, the input bit sequence comprising the first set of payload bits and the second set of payload bits in bit positions within a combined payload of the input bit sequence. At least one bit position of the first set of payload bits has a greater error protection than the bit positions of the second set of payload bits within the combined payload; and outputting the codeword.

In some embodiments, the error correction code is a Polar code.

In some embodiments, the first set of payload bits is included in bit positions with smaller bit indices of the input bit sequence, and the second set of payload bits is included in bit positions with larger bit indices of the input bit sequence.

In some embodiments, the error correction code is a Low Density Parity Check (LDPC) code.

In some embodiments, the first set of payload bits is included in bit positions with higher variable node degree of the LDPC code, and the second set of payload bits is included in bit positions with smaller variable node degree of the LDPC code.

In some embodiments, the input bit sequence further comprises a first set of cyclic redundancy check (CRC) bits, the first set of CRC bits generated from the first set of payload bits.

In some embodiments, the input bit sequence further comprises a second set of CRC bits, the second set of CRC bits generated from the second set of payload bits.

In some embodiments, the method further comprises: encoding the first set of payload bits using an outer code to produce a first set of encoded payload bits, and wherein the input bit sequence comprises the first set of encoded payload bits and the second set of payload bits in bit positions within the combined payload.

In some embodiments, obtaining the first set of bits comprises obtaining bits from at least one first application; obtaining the second set of bits comprises obtaining bits from at least one second application.

In some embodiments, obtaining the first set of bits comprises obtaining bits from at least one first source or for at least one first destination; obtaining the second set of bits comprises obtaining bits from at least one second source or for at least one second destination.

In some embodiments, the method further comprises: including in the combined payload an indication of how many bits are in the first set of bits and how many bits are in the second set of bits.

In some embodiments, the method further comprises: communicating a payload size notification about a payload size of the first set of bits and a payload size of the second set of bits.

In some embodiments, the method further comprises communicating an indication of at least one modulation and coding scheme (MCS) parameter for the first set of bits and at least one MCS parameter for the second set of bits.

In some embodiments, the indication is a single index in an MCS table, each entry in the MCS table having at least one MCS parameter for the first set of bits and at least one MCS parameter for the second set of bits.

In some embodiments, the method further comprises communicating signalling indicating a configuration of the MCS table.

In some embodiments, a performance metric associated with the first set of payload bits is improved over the performance metric associated with the second set of payload bits, the performance metric being at least one of: a packet drop rate, a data rate, a perceived throughput, or a decoding energy consumption.

According to another aspect of the present disclosure, there is provided another method for an encoding apparatus. The method involves obtaining a first set of payload bits having a first priority and a second set of payload bits having a second priority lower than said first priority. An input bit sequence is encoded using an error correction code to produce a codeword, the input bit sequence comprising the first set of payload bits and the second set of payload bits in bit positions within a combined payload of the input bit sequence. At least one bit position of the first set of payload bits has a lower decoding latency than the bit positions of the second set of payload bits within the combined payload; and outputting the codeword.

In some embodiments, the error correction code is a Polar code.

In some embodiments, the first set of payload bits is included in bit positions with smaller bit indices of the input bit sequence, and the second set of payload bits is included in bit positions with larger bit indices of the input bit sequence.

In some embodiments, the error correction code is a Low Density Parity Check (LDPC) code.

In some embodiments, the first set of payload bits is included in bit positions with higher variable node degree of the LDPC code, and the second set of payload bits is included in bit positions with smaller variable node degree of the LDPC code.

In some embodiments, the input bit sequence further comprises a first set of cyclic redundancy check (CRC) bits, the first set of CRC bits generated from the first set of payload bits.

In some embodiments, the input bit sequence further comprises a second set of CRC bits, the second set of CRC bits generated from the second set of payload bits.

In some embodiments, the method further comprises: encoding the first set of payload bits using an outer code to produce a first set of encoded payload bits, and wherein the input bit sequence comprises the first set of encoded payload bits and the second set of payload bits in bit positions within the combined payload.

In some embodiments, obtaining the first set of bits comprises obtaining bits from at least one first application; obtaining the second set of bits comprises obtaining bits from at least one second application.

In some embodiments, obtaining the first set of bits comprises obtaining bits from at least one first source or for at least one first destination; obtaining the second set of bits comprises obtaining bits from at least one second source or for at least one second destination.

In some embodiments, the method further comprises: including in the combined payload an indication of how many bits are in the first set of bits and how many bits are in the second set of bits.

In some embodiments, the method further comprises: communicating a payload size notification about a payload size of the first set of bits and a payload size of the second set of bits.

In some embodiments, the method further comprises communicating an indication of at least one modulation and coding scheme (MCS) parameter for the first set of bits and at least one MCS parameter for the second set of bits.

In some embodiments, the indication is a single index in an MCS table, each entry in the MCS table having at least one MCS parameter for the first set of bits and at least one MCS parameter for the second set of bits.

In some embodiments, the method of claim 28 further comprises communicating signalling indicating a configuration of the MCS table.

In some embodiments, a performance metric associated with the first set of payload bits is improved over the performance metric associated with the second set of payload bits, the performance metric being at least one of: a packet drop rate, a data rate, a perceived throughput, or a decoding energy consumption.

According to another aspect of the present disclosure, there is provided an apparatus comprising: at least one processor; and a non-transitory computer-readable medium having stored thereon, computer-executable instructions, that when executed by the at least one processor, cause the apparatus to perform one of the methods summarized above, or described herein.

According to another aspect of the present disclosure, there is provided a non-transitory computer-readable medium having stored thereon, computer-executable instructions, that when executed by a computer, cause the computer to perform one of the methods summarized above, or described herein.

According to another aspect of the present disclosure, there is provided an apparatus comprising: an encoder input for obtaining a first set of payload bits having a first priority and a second set of payload bits having a second priority lower than said first priority; an encoder for encoding an input bit sequence using an error correction code to produce a codeword, the input bit sequence comprising the first set of payload bits and the second set of payload bits in bit positions within a combined payload of the input bit sequence, wherein at least one bit position of the first set of payload bits has a greater error protection than the bit positions of the second set of payload bits within the combined payload; and an encoder output for outputting the codeword.

According to another aspect of the present disclosure, there is provided an apparatus comprising: an encoder input for obtaining a first set of payload bits having a first priority and a second set of payload bits having a second priority lower than said first priority; an encoder for encoding an input bit sequence using an error correction code to produce a codeword, the input bit sequence comprising the first set of payload bits and the second set of payload bits in bit positions within a combined payload of the input bit sequence, wherein at least one bit position of the first set of payload bits has a lower decoding latency than the bit positions of the second set of payload bits within the combined payload; and an encoder output for outputting the codeword.

### BRIEF DESCRIPTION OF THE DRAWINGS

Embodiments of the disclosure will now be described with reference to the attached drawings in which:

FIG. 1 is a block diagram of a communication system;

FIG. 2 is a block diagram of a communication system;

FIG. 3 is a block diagram of a communication system showing a basic component structure of an electronic device (ED) and a base station;

FIG. 4 is a block diagram of modules that may be used to implement or perform one or more of the steps of embodiments of the application;

FIG. 5A is a process flow for a method of joint encoding provided by an embodiment of the disclosure;

FIGS. 5B and 5C are block diagrams of apparatuses provided by embodiments of the disclosure;

FIG. 6A is a process flow for another method of joint encoding provided by an embodiment of the disclosure, in which an outer code is applied to high priority payload bits;

FIGS. 6B and 6C are block diagrams of apparatuses provided by embodiments of the disclosure;

FIG. 7 is a schematic diagram of a network, joint encoding provided by an embodiment of the disclosure is performed, with prioritization based on source node;

FIG. 8 is a schematic diagram showing the use of signaling to convey an MCS table or indication;

FIG. 9 is a schematic diagram showing the use of signaling to convey a payload size notification, such as payload ratio per type;

FIG. 10 shows an example of a combined payload that includes size indications for each set of payload bits included in the combined payload;

FIG. 11 is a graph showing an example of different reliabilities of bit positions of a 5G NR LDPC code; and

FIG. 12 summarizes different scenarios used for simulations; and

FIGS. 13 to 18 show simulation results.

### DETAILED DESCRIPTION OF THE EMBODIMENTS

The operation of the current example embodiments and the structure thereof are discussed in detail below. It should be appreciated, however, that the present disclosure provides many applicable inventive concepts that can be embodied in any of a wide variety of specific contexts. The specific embodiments discussed are merely illustrative of specific structures of the disclosure and ways to operate the disclosure, and do not limit the scope of the present disclosure.

Some coding schemes produce codewords in which the reliability of the encoded bits in terms of error protection is not equal across the encoded bits. In low density parity check (LDPC) codes for example, bits with a higher variable node degree are usually more reliable.

In polar codes for example, first decoded bits are less prone to error then the subsequently decoded bits. While “reliability” is sometimes used in polar codes to specifically refer to sub-channel capacity or mutual information, “reliability” is used herein in its more general sense: the probability of encoded information being correctly or incorrectly decoded.

It would be desirable to take advantage of this unequal error protection (UEP) property inherent to the payload bits in existing channel coding schemes. However, current wireless communication systems fail to incorporate mechanisms to exploit unequal error protection at the air interface. In existing channel coding schemes, higher-layer data from different applications or sources are grouped into separate payloads, and are then encoded, transmitted, and decoded separately. In 5G for example, transmissions requiring extra reliability and lower latency can be encoded using lower-rate codes, as specified by a low spectral efficiency (SE) modulation and coding scheme (MCS) table; however, the same code rate and MCS is applied to an entire codeword and this approach fails to leverage unequal error protection.

Accordingly, embodiments of the present disclosure relate to a dedicated and complete design for unequal error protection in a single forward error correction codeword at the air interface layer of wireless communication networks.

To simultaneously solve the two problems of (i) providing differential treatment for high and low priority payloads (e.g. higher QoS for payload with higher priority), and (ii) enhancing the overall coding gain through the use of longer codewords, a joint coding scheme is provided in which a high-priority payload is combined with a low priority payload, and a combined payload is jointly encoded to generate a single long codeword.

The higher coding gain is achieved by longer code length, compared to the code length that would be used if the payloads were encoded separately.

The encoder design takes into account a priority order of the payloads to be combined. Thus, the encoder is able to provide better error protection for the payload with higher priority compared to the payload with lower priority. In some embodiments, the priority of input payloads is based on a reliability requirement of each payload, for example in terms of block error rate (BLER). For example, if a first payload has a higher BLER requirement than a second payload, the two payloads can be combined in the single larger codeword to provide better error protection to the first payload compared to the second payload.

In some embodiments, the priority can be associated with payload type. For example: one or more small URLLC messages (e.g. from sensors) can be combined with a video payload or an eMBB payload. In this case, the multiple payloads (URLLC messages plus video payload) are combined and transmitted in one larger forward error correction (FEC) codeword. For example, the URLLC messages may be assigned a higher priority than video payloads. In this case, a URLLC message and a video payload can be combined in a single larger codeword in a manner that provides better error protection to the URRLC message compared to the video payload.

In some embodiments, the priority of input payloads (or sets of inputs bits) is based on the source of each input payload.

Payloads may come from different sources, e.g., in a relay and multi-hop scenario, each source having a respective priority.

In some embodiments, a separate CRC for each payload is included to allow individual payload decoding. When a payload fails to be decoded, a Hybrid automatic repeat request (HARQ) scheme is used to request a retransmission of the joint codeword.

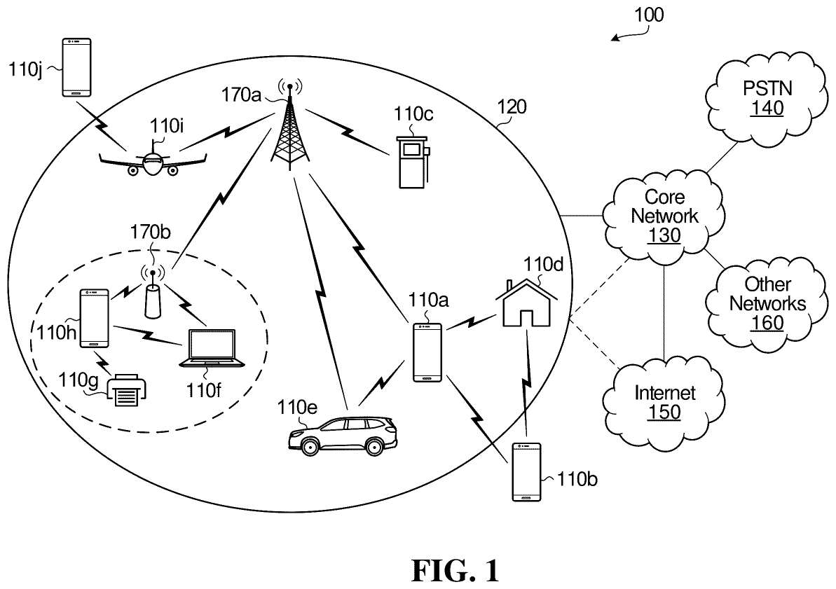

Referring to FIG. 1, as an illustrative example without limitation, a simplified schematic illustration of a communication system is provided. The communication system 100 comprises a radio access network 120. The radio access network 120 may be a next generation (e.g. sixth generation (6G) or later) radio access network, or a legacy (e.g. 5G, 4G, 3G or 2G) radio access network. One or more communication electric device (ED) 110a-120j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160. In the system of FIG. 1, in some embodiments, a component of the radio access network, for example base station 170a, and/or the EDs, are configured to execute one of the encoding methods described herein and/or corresponding decoding methods.

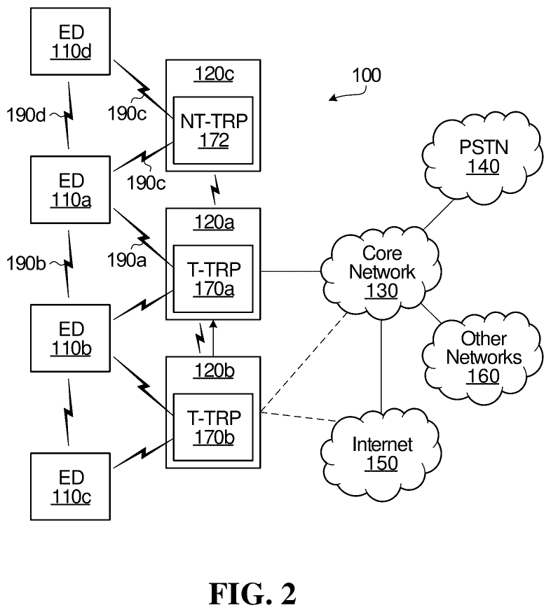

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast and unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of the terrestrial communication system and the non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing, and faster physical layer link switching between terrestrial networks and non-terrestrial networks.

The terrestrial communication system and the non-terrestrial communication system could be considered sub-systems of the communication system. In the example shown, the communication system 100 includes electronic devices (ED) 110a-110d (generically referred to as ED 110), radio access networks (RANs) 120a-120b, non-terrestrial communication network 120c, a core network 130, a public switched telephone network (PSTN) 140, the internet 150, and other networks 160. The RANs 120a-120b include respective base stations (BSs) 170a-170b, which may be generically referred to as terrestrial transmit and receive points (T-TRPs) 170a-170b. The non-terrestrial communication network 120c includes an access node 120c, which may be generically referred to as a non-terrestrial transmit and receive point (NT-TRP) 172.

Any ED 110 may be alternatively or additionally configured to interface, access, or communicate with any other T-TRP 170a-170b and NT-TRP 172, the internet 150, the core network 130, the PSTN 140, the other networks 160, or any combination of the preceding. In some examples, ED 110a may communicate an uplink and/or downlink transmission over an interface 190a with T-TRP 170a. In some examples, the EDs 110a, 110b and 110d may also communicate directly with one another via one or more sidelink air interfaces 190b. In some examples, ED 110d may communicate an uplink and/or downlink transmission over an interface 190c with NT-TRP 172.

The air interfaces 190a and 190b may use similar communication technology, such as any suitable radio access technology. For example, the communication system 100 may implement one or more channel access methods, such as code division multiple access (CDMA), time division multiple access (TDMA), frequency division multiple access (FDMA), orthogonal FDMA (OFDMA), or single-carrier FDMA (SC-FDMA) in the air interfaces 190a and 190b. The air interfaces 190a and 190b may utilize other higher dimension signal spaces, which may involve a combination of orthogonal and/or non-orthogonal dimensions.

The air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs and one or multiple NT-TRPs for multicast transmission.

The RANs 120a and 120b are in communication with the core network 130 to provide the EDs 110a 110b, and 110c with various services such as voice, data, and other services. The RANs 120a and 120b and/or the core network 130 may be in direct or indirect communication with one or more other RANs (not shown), which may or may not be directly served by core network 130, and may or may not employ the same radio access technology as RAN 120a, RAN 120b or both. The core network 130 may also serve as a gateway access between (i) the RANS 120a and 120b or EDs 110a 110b, and 110c or both, and (ii) other networks (such as the PSTN 140, the internet 150, and the other networks 160). In addition, some or all of the EDs 110a 110b, and 110c may include functionality for communicating with different wireless networks over different wireless links using different wireless technologies and/or protocols. Instead of wireless communication (or in addition thereto), the EDs 110a 110b, and 110c may communicate via wired communication channels to a service provider or switch (not shown), and to the internet 150. PSTN 140 may include circuit switched telephone networks for providing plain old telephone service (POTS). Internet 150 may include a network of computers and subnets (intranets) or both, and incorporate protocols, such as Internet Protocol (IP), Transmission Control Protocol (TCP), User Datagram Protocol (UDP). EDs 110a 110b, and 110c may be multimode devices capable of operation according to multiple radio access technologies, and incorporate multiple transceivers necessary to support such.

In the system of FIG. 2, in some embodiments, a component of the radio access network, for example, the TRPs, and/or the EDs, are configured to execute one of the encoding methods described herein and/or corresponding decoding methods.

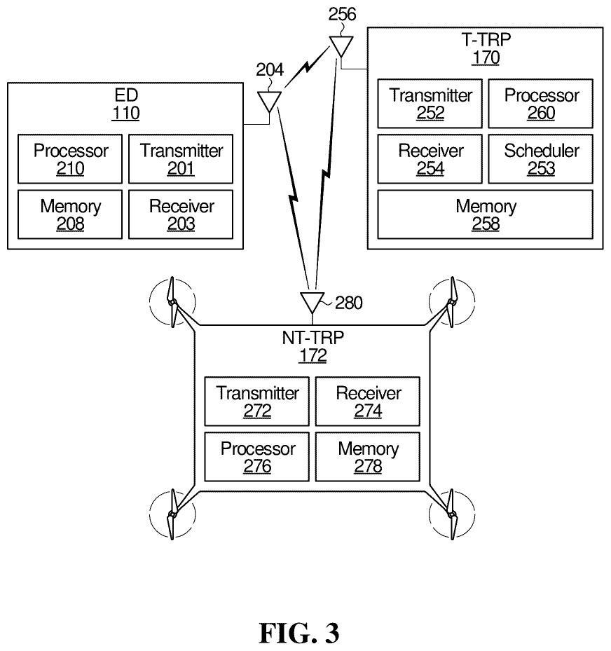

FIG. 3 illustrates another example of an ED 110 and a base station 170a, 170b and/or 170c. The ED 110 is used to connect persons, objects, machines, etc. The ED 110 may be widely used in various scenarios, for example, cellular communications, device-to-device (D2D), vehicle to everything (V2X), peer-to-peer (P2P), machine-to-machine (M2M), machine-type communications (MTC), internet of things (IOT), virtual reality (VR), augmented reality (AR), industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, an industrial device, or apparatus (e.g. communication module, modem, or chip) in the forgoing devices, among other possibilities. Future generation EDs 110 may be referred to using other terms. The base station 170a and 170b is a T-TRP and will hereafter be referred to as T-TRP 170. Also shown in FIG. 3, a NT-TRP will hereafter be referred to as NT-TRP 172. Each ED 110 connected to T-TRP 170 and/or NT-TRP 172 can be dynamically or semi-statically turned-on (i.e., established, activated, or enabled), turned-off (i.e., released, deactivated, or disabled) and/or configured in response to one of more of: connection availability and connection necessity.

The ED 110 includes a transmitter 201 and a receiver 203 coupled to one or more antennas 204. Only one antenna 204 is illustrated. One, some, or all of the antennas may alternatively be panels. The transmitter 201 and the receiver 203 may be integrated, e.g. as a transceiver. The transceiver is configured to modulate data or other content for transmission by at least one antenna 204 or network interface controller (NIC). The transceiver is also configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by the processing unit(s) 210. Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache, and the like.

The ED 110 may further include one or more input/output devices (not shown) or interfaces (such as a wired interface to the internet 150 in FIG. 1). The input/output devices permit interaction with a user or other devices in the network. Each input/output device includes any suitable structure for providing information to or receiving information from a user, such as a speaker, microphone, keypad, keyboard, display, or touch screen, including network interface communications.

The ED 110 further includes a processor 210 for performing operations including those related to preparing a transmission for uplink transmission to the NT-TRP 172 and/or T-TRP 170, those related to processing downlink transmissions received from the NT-TRP 172 and/or T-TRP 170, and those related to processing sidelink transmission to and from another ED 110. Processing operations related to preparing a transmission for uplink transmission may include operations such as encoding, modulating, transmit beamforming, and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g. by detecting and/or decoding the signaling). An example of signaling may be a reference signal transmitted by NT-TRP 172 and/or T-TRP 170. In some embodiments, the processor 276 implements the transmit beamforming and/or receive beamforming based on the indication of beam direction, e.g. beam angle information (BAI), received from T-TRP 170. In some embodiments, the processor 210 may perform operations relating to network access (e.g. initial access) and/or downlink synchronization, such as operations relating to detecting a synchronization sequence, decoding and obtaining the system information, etc. In some embodiments, the processor 210 may perform channel estimation, e.g. using a reference signal received from the NT-TRP 172 and/or T-TRP 170.

Although not illustrated, the processor 210 may form part of the transmitter 201 and/or receiver 203. Although not illustrated, the memory 208 may form part of the processor 210.

The processor 210, and the processing components of the transmitter 201 and receiver 203 may each be implemented by the same or different one or more processors that are configured to execute instructions stored in a memory (e.g. in memory 208). Alternatively, some or all of the processor 210, and the processing components of the transmitter 201 and receiver 203 may be implemented using dedicated circuitry, such as a programmed field-programmable gate array (FPGA), a graphical processing unit (GPU), or an application-specific integrated circuit (ASIC).

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP)), a site controller, an access point (AP), or a wireless router, a relay station, a remote radio head, a terrestrial node, a terrestrial network device, or a terrestrial base station, base band unit (BBU), remote radio unit (RRU), active antenna unit (AAU), remote radio head (RRH), central unit (CU), distribute unit (DU), positioning node, among other possibilities. The T-TRP 170 may be macro BSs, pico BSs, relay node, donor node, or the like, or combinations thereof. The T-TRP 170 may refer to the forging devices or apparatus (e.g. communication module, modem, or chip) in the forgoing devices.

In some embodiments, the parts of the T-TRP 170 may be distributed. For example, some of the modules of the T-TRP 170 may be located remote from the equipment housing the antennas of the T-TRP 170, and may be coupled to the equipment housing the antennas over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment housing the antennas of the T-TRP 170. The modules may also be coupled to other T-TRPs. In some embodiments, the T-TRP 170 may actually be a plurality of T-TRPs that are operating together to serve the ED 110, e.g. through coordinated multipoint transmissions.

The T-TRP 170 includes at least one transmitter 252 and at least one receiver 254 coupled to one or more antennas 256. Only one antenna 256 is illustrated. One, some, or all of the antennas may alternatively be panels. The transmitter 252 and the receiver 254 may be integrated as a transceiver. The T-TRP 170 further includes a processor 260 for performing operations including those related to: preparing a transmission for downlink transmission to the ED 110, processing an uplink transmission received from the ED 110, preparing a transmission for backhaul transmission to NT-TRP 172, and processing a transmission received over backhaul from the NT-TRP 172. Processing operations related to preparing a transmission for downlink or backhaul transmission may include operations such as encoding, modulating, precoding (e.g. MIMO precoding), transmit beamforming, and generating symbols for transmission. Processing operations related to processing received transmissions in the uplink or over backhaul may include operations such as receive beamforming, and demodulating and decoding received symbols. The processor 260 may also perform operations relating to network access (e.g. initial access) and/or downlink synchronization, such as generating the content of synchronization signal blocks (SSBs), generating the system information, etc. In some embodiments, the processor 260 also generates the indication of beam direction, e.g. BAI, which may be scheduled for transmission by scheduler 253. The processor 260 performs other network-side processing operations described herein, such as determining the location of the ED 110, determining where to deploy NT-TRP 172, etc. In some embodiments, the processor 260 may generate signaling, e.g. to configure one or more parameters of the ED 110 and/or one or more parameters of the NT-TRP 172. Any signaling generated by the processor 260 is sent by the transmitter 252. Note that “signaling”, as used herein, may alternatively be called control signaling. Dynamic signaling may be transmitted in a control channel, e.g. a physical downlink control channel (PDCCH), and static or semi-static higher layer signaling may be included in a packet transmitted in a data channel, e.g. in a physical downlink shared channel (PDSCH).

A scheduler 253 may be coupled to the processor 260. The scheduler 253 may be included within or operated separately from the T-TRP 170, which may schedule uplink, downlink, and/or backhaul transmissions, including issuing scheduling grants and/or configuring scheduling-free (“configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or receiver 254. Also, although not illustrated, the processor 260 may implement the scheduler 253. Although not illustrated, the memory 258 may form part of the processor 260.

The processor 260, the scheduler 253, and the processing components of the transmitter 252 and receiver 254 may each be implemented by the same or different one or more processors that are configured to execute instructions stored in a memory, e.g. in memory 258. Alternatively, some or all of the processor 260, the scheduler 253, and the processing components of the transmitter 252 and receiver 254 may be implemented using dedicated circuitry, such as a FPGA, a GPU, or an ASIC.

Although the NT-TRP 172 is illustrated as a drone only as an example, the NT-TRP 172 may be implemented in any suitable non-terrestrial form. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110, processing an uplink transmission received from the ED 110, preparing a transmission for backhaul transmission to T-TRP 170, and processing a transmission received over backhaul from the T-TRP 170. Processing operations related to preparing a transmission for downlink or backhaul transmission may include operations such as encoding, modulating, precoding (e.g. MIMO precoding), transmit beamforming, and generating symbols for transmission. Processing operations related to processing received transmissions in the uplink or over backhaul may include operations such as receive beamforming, and demodulating and decoding received symbols. In some embodiments, the processor 276 implements the transmit beamforming and/or receive beamforming based on beam direction information (e.g. BAI) received from T-TRP 170. In some embodiments, the processor 276 may generate signaling, e.g. to configure one or more parameters of the ED 110. In some embodiments, the NT-TRP 172 implements physical layer processing, but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or receiver 274. Although not illustrated, the memory 278 may form part of the processor 276.

The processor 276 and the processing components of the transmitter 272 and receiver 274 may each be implemented by the same or different one or more processors that are configured to execute instructions stored in a memory, e.g. in memory 278. Alternatively, some or all of the processor 276 and the processing components of the transmitter 272 and receiver 274 may be implemented using dedicated circuitry, such as a programmed FPGA, a GPU, or an ASIC. In some embodiments, the NT-TRP 172 may actually be a plurality of NT-TRPs that are operating together to serve the ED 110, e.g. through coordinated multipoint transmissions.

The T-TRP 170, the NT-TRP 172, and/or the ED 110 may include other components, but these have been omitted for the sake of clarity.

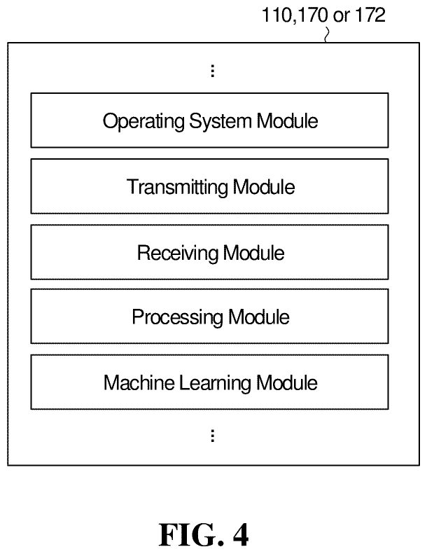

One or more steps of the embodiment methods provided herein may be performed by corresponding units or modules, according to FIG. 4. FIG. 4 illustrates units or modules in a device, such as in ED 110, in T-TRP 170, or in NT-TRP 172. For example, a signal may be transmitted by a transmitting unit or a transmitting module. For example, a signal may be transmitted by a transmitting unit or a transmitting module. A signal may be received by a receiving unit or a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be an integrated circuit, such as a programmed FPGA, a GPU, or an ASIC. It will be appreciated that where the modules are implemented using software for execution by a processor for example, they may be retrieved by a processor, in whole or part as needed, individually or together for processing, in single or multiple instances, and that the modules themselves may include instructions for further deployment and instantiation.

Additional details regarding the EDs 110, T-TRP 170, and NT-TRP 172 are known to those of skill in the art. As such, these details are omitted here.

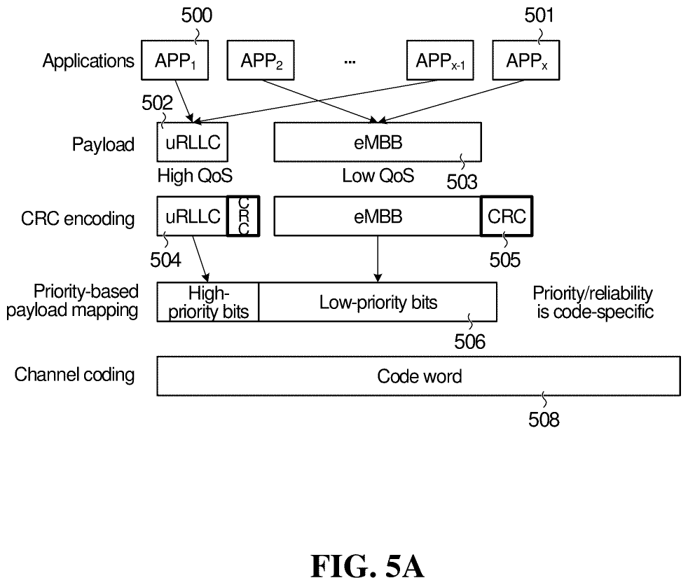

A detailed method of joint coding with different priorities is described below with reference to FIG. 5A. The example of FIG. 5A shows a joint coding of two packets, an ultra reliable low latency (uRLLC) packet and an eMBB packet. In practice, there can be more than two packets jointly encoded, and uRLLC and eMBB are just specific examples of the types of such packets. While packets are referred to, more generally, the method can be applied to multiple sets of payload bits to be combined in a single codeword. While “packet” can refer to a bundle of information at various networking layers, the present disclosure describes a physical layer operation, namely, channel coding; therefore, “packet” is primarily used herein to describe a physical layer packet, unless otherwise specified. Moreover, a physical layer packet is often referred to as a “payload” in channel coding, so these two terms may be used interchangeably herein.

Referring now to FIG. 5A, shown is a process flow for a method of joint encoding provided by an embodiment of the disclosure. As shown in FIG. 5A, there are multiple sets of bits 500, . . . , 501 to transmit. These may, for example, be bits from different applications (APP₁, . . . ,APPₓ) as shown in FIG. 5A, or may be bits received from different sources. Each of the sets of bits 500, . . . ,501 is included in one of at least two sets of payload bits 502,503 based on priority. The example of FIG. 5A shows two sets of payload bits, but there can be a larger number of sets of payload bits.

The first set of payload bits 502 has a first priority, and a second set of payload bits 503 has a second priority lower than the first priority. More generally, each set of payload bits has a respective priority. In the specific example illustrated, the first (higher) priority set of payload bits includes uRLLC bits, and the second (lower) priority set of payload bits includes eMBB bits.

Optionally in some embodiments, one or more sets of payload bits are CRC encoded separately to produce a respective CRC encoded payload to allow separate decoding at the receiver. For example, because at least one set of payload bits is CRC encoded, a decoder can terminate the decoding of the entire codeword once a CRC check passes for a first set of CRC encoded bits. Thus, the remaining undecoded bits are discarded and the first CRC encoded bits are decoded separately from the other, lower priority bits. In this scenario, the lower priority bits may be separately decoded later, after a HARQ retransmission for example. In the example of FIG. 5A, both sets of payload bits are CRC encoded, and the CRC encoded payloads are indicated at 504,505, including a CRC encoded high priority payload and a CRC encoded low priority payload. In some embodiments, the CRC encoding step is omitted for one or more, or all, of the sets of payload bits.

An input bit sequence 506 to the channel coding step is based on the sets of input bits 502,503 (or corresponding CRC encoded payloads 504,505 for each set of input bits for which CRC encoding is included). The bits of the first set of payload bits 502 and the second set of payload bits 503 are included as a combined payload 506 in the input bit sequence. The bit positions of the first set of payload bits are chosen such that, within the combined payload, following channel coding, those bit positions will have a greater error protection than the bit positions of the second set of payload bits within the combined payload. More generally, at least one bit position of the first set of payload bits, within the combined payload, will have a greater error protection than the bit positions of the second set of payload bits within the combined payload. The input bit sequence 506 may be obtained, for example, by mapping bits from the first set of payload bits and the second set of payload bits to positions within the input bit sequence 506. Next channel coding is applied to the input bit sequence to produce a code word 508.

The error protection of the bit positions is dictated by the particular channel code being implemented. As such, the sets of input bits may be included in different bit positions within the input bit sequence 506 depending on the particular channel code. In some embodiments, the bit positions of the first set of payload bits having a greater error protection than the bit positions of the second set of payload bits within the input bit sequence refers to the average reliability for bits of the first set of bits being higher compared to the average reliability for bits of the second set of bits. In another embodiment, the bit positions of the first set of payload bits having a greater error protection than the bit positions of the second set of payload bits within the input bit sequence refers to the probability of error of a packet containing the first set of bits being lower than the probability of error of a packet containing the second set of bits. Specific examples of how the bit positions may be determined for polar and LDPC codes are described below.

In some embodiments, for example to allow for early termination, the bit positions for the first set of payload bits and the second set of payload bits are not interspersed, even though bit-position-wise reliability may dictate this. For example, with a polar code, bits of a first packet having higher priority, may all be mapped to bit positions that are lower than bit positions used for bits of a second packet having lower priority. For example, the bits of the first packet or set of payload bits are included in bit positions with smaller bit indices of the input bit sequence, and the bits of the second packet or set of payload bits are included in bit positions with larger bit indices. This can result in some individual bit positions used for the higher priority packet being more reliable, in the Polar coding sense, than some individual bit positions used for the lower priority packet. However, because with polar coding, a later bit can only be decoded correctly if previous bits have been decoded, the earlier bit positions have better error protection.

In some embodiments, one or more performance metrics associated with the first set of payload bits is improved over the performance metric(s) associated with the second set of payload bits. The performance metrics may include at least one of:
a packet drop rate: this metric is usually perceived at a higher sub-layer but could be measured or affected at the physical layer as well, where the decoder either claims a success (for example CRC passed) or a failure (CRC not passed), and there is no state in between (such as a soft output). The packet drop rate is defined as the probability of decoding failure which is not to be recovered by a HARQ scheme;
a data rate: this metric refers to, for example, the amount of bits transmitted per second. It could be information data rates (number of information bits per second) or coded data rates (number of coded bits per second);
a perceived throughput, or the application-level throughput: this metric is defined at upper layers and not necessarily the actual data rate defined above. It is application-specific. For example, “360p”, “720p”, or “1080p” for video streaming.

a decoding energy consumption: this metric is the energy or power consumed during decoding, usually measured by J, or J/bit or Watt. Like decoding latency, a low energy consumption can be achieved by early termination of the decoder once the target payload has been decoded. Sometimes this metric grows larger with decoding latency, and sometimes not.

In a specific example, the first priority set of payload bits includes uRLLC bits, and the second priority set of payload bits includes eMBB bits. For example, denote a set of k₀ uRLLC payload bits as u₀, and denote a set of k₁ eMBB payload bits as u₁. A CRC encoded uRLLC payload may be denoted as a vector u′₀ of length k′₀ and the CRC encoded eMBB payload may be denoted as a vector u′₁ of length k′₁. Denote an input bit sequence for channel encoding as v; which is based on the CRC encoded payloads. This may be achieved by including bits from the CRC encoded payloads in bit positions within the input bit sequence v, such that the bit positions of the CRC encoded uRLLC payload have a greater error protection than the bit positions of the CRC encoded eMBB payload within a combined payload of the input bit sequence. There are a total of k bits from u′₀and u′₁ to be included in the combined payload, where k=k′₀+k′₁. Denote the set of k bits of the combined payload as u, containing bits as u (i), for i=1 to k. The input bit sequence v contains bits v(i), for i=1 to k, where v (i) has input bit position i. The input bits from u(i) are included in respective input bit positions of v in accordance with a set of indexes j₁, . . . ,jₖ, meaning that v(i)=u(jᵢ), equivalently, v= [u (j.), . . . , u(jₖ)]. The way in which the input bits u (i) are included in the input bit sequence v can be viewed as a mapping u→>v=[u(j₁), . . . , u(jₖ)]. Specific examples of the mapping are detailed below. Next, channel coding is applied to the input bit sequence v to produce a code word. For example, denote by G the generator matrix of the adopted channel code, the encoding process produces c=vG, where c is the codeword.

Referring now to FIG. 5B, shown is a block diagram of an apparatus provided by an embodiment of the application. The apparatus has an encoder input 540 for obtaining a first set of payload bits 542 having a first priority and a second set of payload bits 544 having a second priority lower than said first priority. There is an encoder 546 for encoding an input bit sequence using an error correction code to produce a codeword. The input bit sequence includes the first set of payload bits and the second set of payload bits in bit positions within a combined payload of the input bit sequence. At least one bit position of the first set of payload bits has a greater error protection than the bit positions of the second set of payload bits within the combined payload. There is an encoder output 548 for outputting the codeword.

Alternatively, in FIG. 5B, the encoder 546 is for encoding an input bit sequence using an error correction code to produce a codeword, the input bit sequence comprising the first set of payload bits and the second set of payload bits in bit positions within a combined payload of the input bit sequence, and at least one bit position of the first set of payload bits has a lower decoding latency than the bit positions of the second set of payload bits within the combined payload.

Referring now to FIG. 5C, in a variant of the embodiment of FIG. 5B, the encoder of FIG. 5B is replaced with a mapper 550 that maps the input bits to bit positions in the input bit sequence and a channel encoder 552 that performs channel encoding using the input sequence thus produced.

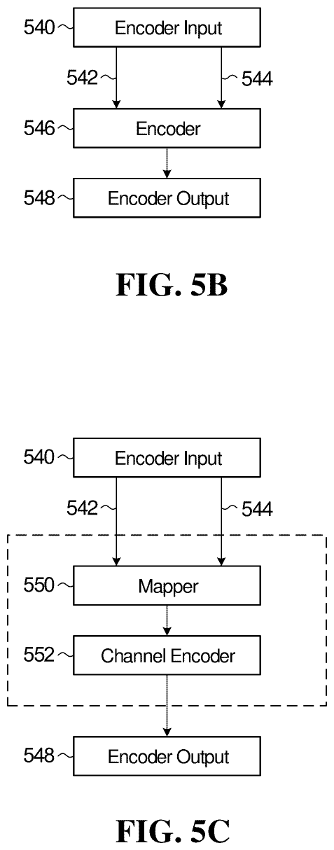

Referring now to FIG. 6A, in a variant of the approach shown in FIG. 5A, the first set of input bits (or the first set plus CRC), namely the set of input bits with higher priority, is further subject to an outer encoding step for extra reliability. This results in a set of encoded payload bits 600. In this case, the input bit sequence is formed from the encoded payload bits and the second set of payload bits.

Referring now to FIGS. 6B and 6C, shown are block diagrams of apparatuses provided by embodiments of the application. The embodiments of FIGS. 6B and 6C differ from those of FIGS. 5B and 5C described above in that an outer encoder 560 is provided between input 540 and the encoder 546 (FIG. 5B) or mapper 550 (FIG. 5C). The outer encoder 560 performs outer encoding for the first set of payload bits 542. In some embodiments, an additional outer encoder is provided for performing outer encoding for the second set of payload bits.

Continuing with the detailed example introduced above, in which the first priority set of payload bits includes uRLLC bits, and the second priority set of payload bits includes eMBB bits, in a case where outer coding is included for the high priority payload (e.g., a uRLLC payload), denote the uRLLC payload and eMBB payload after CRC encoding as u′₀ of length k′₀ and u′₁ of length k′₁, respectively. The uRLLC part is further encoded by an outer code, e.g., a Reed-Solomon (RS) code or a Bose-Chaudhuri-Hocquenghem (BCH) code, with a generator matrix F. The outer encoding process is denoted by u′₀F. Then, the priority-based mapping produces v=[u(i₀), u(i₁), . . . , u(iₖ)], where u=[u′₀F,u′₁]. Finally, as before the encoding process is c=vG.

As described above, a first set of payload bits has a first priority and a second set of payload bits has a second priority lower than said first priority. Various examples of prioritization have been described above, including prioritization based on a reliability requirement, packet type, and source. More details of these types of prioritization are provided below. Prioritization may be performed on other bases than those specifically disclosed.

In some embodiments, priority is source node, destination node, or user based: in this case, the bits of the combined payload are mapped to, and/or included in, the input bit sequence for channel coding based on source node, or destination node, or user priority. In this case, the bit positions with greater error protection and/or lowest latency are allocated for payloads for higher-priority source nodes, or destination nodes, or users. This can involve prioritizing payloads from different sources, or payloads to different destinations, or payloads for different routing paths (sources & destinations), or payloads for different users.

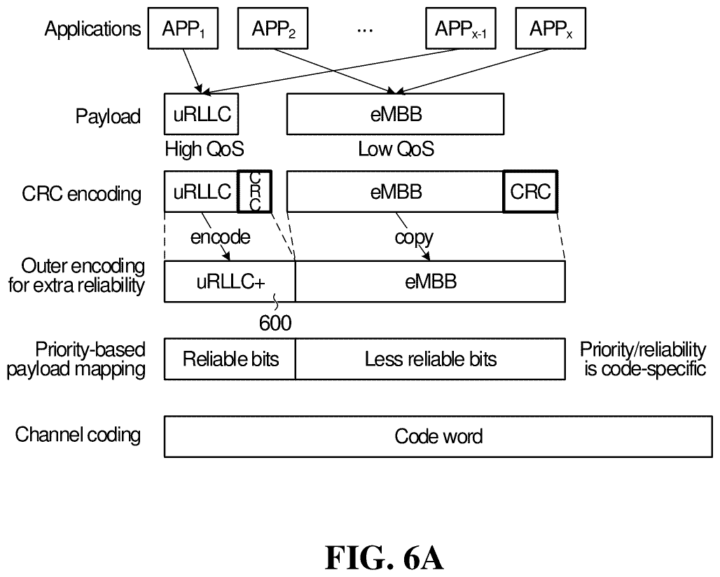

An example of source node priority is shown in FIG. 7. Shown is a relay node 712 that receives payloads from multiple source nodes, including a source node 1 700 that is high priority, source node 2 702 that is medium priority, and source node 3 704 that is low priority. The relay node 712 receives a high priority payload 706, medium priority payload 708, and low priority payload 710. These are combined by the relay node 712 into a multi-payload FEC codeword 714 using the method described above and then transmitted to a destination node 716.

In some embodiments, a new MCS table design is employed. The long-standing concept of code rate (CR) may be replaced in the new MCS table. When payloads are coded individually, in accordance with conventional methods, the code rate represents the ratio between payload size and code length. However, in joint coding, the payload size divided by code length is no longer the code rate. In some embodiments, a new parameter referred to as the “payload rate” (PR) is defined. This can be determined for each set of payload bits. The payload rate is for a given set of payload bits is defined as the number of bits in that set of payload bits divided by the length of the entire codeword. For example, a codeword may have first and second payloads with length K1 and K2, and let K=K1+K2. In this case, the overall code rate is K/N, and the payload rates are K1/N and K2/N, for the first and second payloads respectively.

The sum of payload rates of all of the sets of bits included in the input bit sequence equals the code rate for the codeword as a whole. For example, the code rate can be defined as follows:

$$CR = {PR}_{1} + {PR}_{2} + … {PR}_{i}$$

With conventional codes, the error correction performance depends on the code rate, whereas here the error correction performance mainly depends on the payload rate.

With this in mind, the MCS table can be modified to include multiple payload rates instead of a single code rate. This may be done by specifying a new MCS table to ensure the block error rate (BLER) performance of multiple types of packets.

For example, a MCS table may be defined to ensure BLER (uRLLC)=10⁻⁵, and BLER (eMBB)=10⁻². A new MCS table can be defined for joint uRLLC-eMBB coding, and may contain new columns for each type of packet. While conventional MCS tables only support a single target error rate, the newly introduced one supports multiple target error rates.

In a specific example, the MCS table may look like the Table 1 below. There may be multiple columns corresponding to the multiple sets of payload bits (packets) encoded. Each column specifies the payload rate of each packet.

TABLE 1
MCS for Joint Encoding

| MCS | Modulation | Target payload | Target payload | Overall |
|---|---|---|---|---|
| Index | Order | Rate 1 × | Rate 2 × | spectral |
| I_{MCS} | Qₘ | [1024] R₁ | [1024] R₂ | efficiency |
| 0 | 2 | 30 | 90 | 0.2344 |
| 1 | 2 | 39 | 118 | 0.3066 |
| 2 | 2 | 48 | 145 | 0.3770 |
| 3 | 2 | 63 | 188 | 0.4902 |
| . . . | . . . | . . . | . . . | . . . |
| 28 | 6 | 237 | 711 | 5.5547 |

| | | |
|---|---|---|
| 29 | 2 | Reserved |
| 30 | 4 | Reserved |
| 31 | 6 | Reserved |

In some embodiments, the new MCS tables that are suitable for jointly encoded payloads will be configured by radio resource control (RRC) or radio network temporary identifier (RNTI) signaling. Furthermore, the use of a previously configured table (including the new MCS table), as among a set of possible tables can also be indicated using signaling. For example, the newly introduced RRC parameters may be: PUSCH/PDSCH-Config, or

ConfiguredGrantConfig ::= SEQUENCE {
...
mcs-Table

ENUMERATED {..., Joint-coding M₁-QAM, Joint-coding M₂-

QAM}
mcs-TableTransformPrecoder ENUMERATED {..., Joint-coding M₁-QAM, Joint-coding M₂-
QAM}
...
}

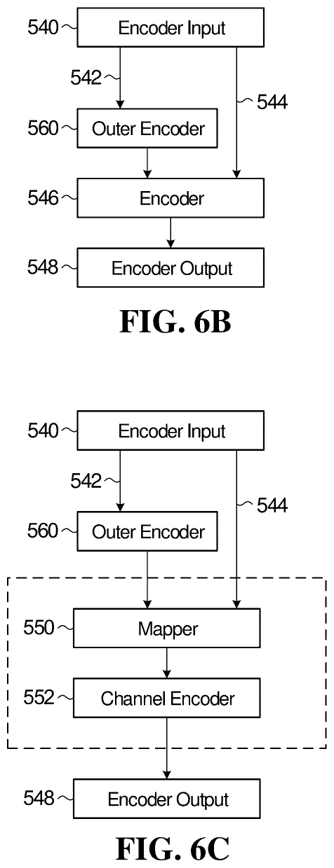

FIG. 8 shows an example of signaling from a gNB 800 to a UE 802, via RRC information element (IE) 804 or RNTI, indicating/configuring an MCS table, referred to as MCS Table IV 806 in the illustrated example, for joint coding of M-QAM.

The newly introduced MCS table supports multiple target packet error rates (PER) for different payloads. By adjusting the payload rates, it is possible to meet the diverse QoS requirements in 6G.

In addition to MCS, downlink control information (DCI) (for downlink transmission) and uplink control information (UCI) (for uplink transmission) (e.g. UCI indicators 1_0, 1_1) may be used to inform the receiver about the payload size of each type of packet. This is called the “payload size notification”.

The number of payload bits encoded in a codeword for each type of packet may be as follows:
{K₁,K₂, . . . } or {N_{info1}, N_{info2}, . . . } or {R₁,R₂, . . . }

Or equivalently, the information bit ratio of each type of packet can be used:
P_{URLLC}=K_{URLLC}/(K_{URLLC}+K_{eMBB}) or P=K_{URLLC}/K_{eMBB} or {P₁,P₂, . . . }

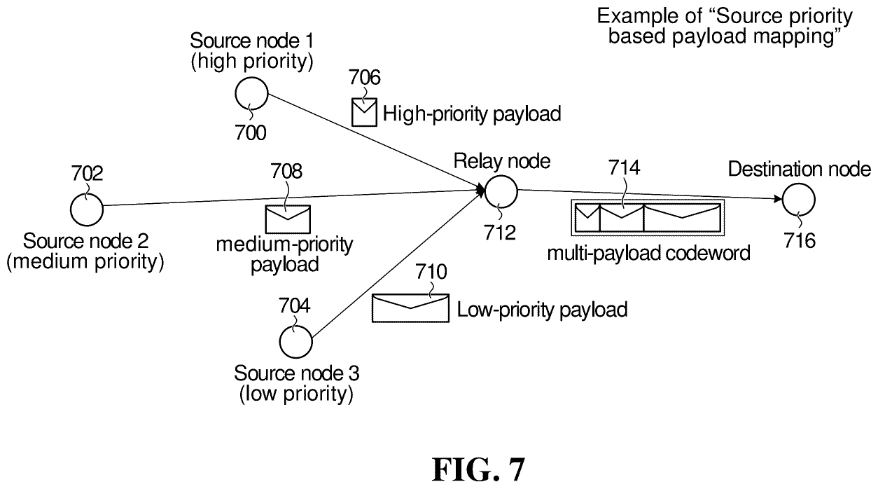

FIG. 9 shows an example of signaling from a gNB 900 to a UE 902, via DCI 904, or signaling from the UE 902 to the gNB 900 via UCI 906, of the payload size/ratio 908 for each type of packet.

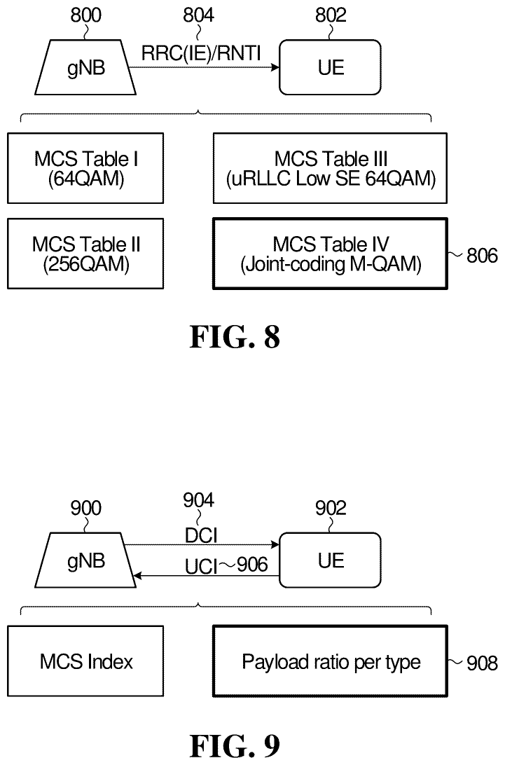

In some embodiments, the transmitter does not send this information separately in UCI/DCI, but instead embeds this payload size information in the information bits. In such a way, the decoder will find out, as it decodes, the payload size for each packet, and output the intended decoding results accordingly. An example is shown in FIG. 10. Here the overall information bit stream includes a first size indicator 1000, first set of bits 1002 (more reliable bits in the example), a second size indicator 1004, second set of bits 1006 (less reliable bits in the example), a third size indicator 1008, third set of bits 1010 (least reliable bits in the example).

The payload size notification methods provide the much desired flexibility to support various payload rates. This allows the communication system to adaptively adjust the payload rates of different packets, in order to fulfill the diverse QoS requirements.

### Polar Coding

In some embodiments, the channel coding involves the use of a polar code. For polar codes, unequal error protection can be achieved with successive cancellation (SC)-based decoding algorithms, including successive cancellation list (SCL) decoding. Due to sequential decoding, a successful decoding of each information bit requires that all its preceding information bits are decoded correctly. Thus, information bits with smaller bit indices are “better protected”, despite potentially having lower sub-channel capacity, as will be explained below.

For a length-16 polar code used in the examples described below, its sub-channel capacity sequence table is as follows:

| W (Qᵢ^{Nmax}) | Qᵢ^{Nmax} | W (Qᵢ^{Nmax}) | Qᵢ^{Nmax} | W (Qᵢ^{Nmax}) | Qᵢ^{Nmax} | W (Qᵢ^{Nmax}) | Qᵢ^{Nmax} |
|---|---|---|---|---|---|---|---|
| 0 | 0 | 4 | 8 | 8 | 6 | 12 | 11 |
| 1 | 1 | 5 | 3 | 9 | 10 | 13 | 13 |
| 2 | 2 | 6 | 5 | 10 | 12 | 14 | 14 |
| 3 | 4 | 7 | 9 | 11 | 7 | 15 | 15 |

The sub-channel capacity sequence table specifies an ordered sequence for a given length polar code. The odd columns show relative rank of sub-channel capacities, also known as mutual information, in ascending order of capacity, and the even columns show corresponding bit indices of the polar code sequence, also known as sub-channels. Other table formats or presentations may show an absolute capacity value, rather than a relative rank.

In a specific example, there are two packets that are to be jointly encoded into a length 16 polar code codeword, including a high-priority packet of 2 bits and low-priority packet of 4 bits. In total, there are 6 information bits and 10 frozen bits. The least capacity bit positions are used for the frozen bits, and the remaining bit positions for information bits. According to the table, the 10 frozen bit indices are [0,1,2,4,8,3,5,9,6,10]. The 6 information bit indices, in ascending capacity order are [12,7,11,13,14,15], among which the high-priority packet [Uₕ₁,Uₕ₂] is mapped to [7,11] and the low-priority packet [Uₗ₁, uₗ₂, uₗ₃, u₄] is mapped to [12,13,14,15]. The high priority packet is mapped to the lowest bit positions as among the information bit positions, as they are decoded first. In addition, if the lower (earlier) bit positions are not decoded properly, then the higher (later) bit positions cannot be decoded at all. As such, while individual bit position capacity may be lower for the higher priority bits relative to some of the low priority bits, the probability of error for the high priority packet is lower than that of the low priority packet, as the low priority packet cannot even be decoded unless the high priority packet is successful. From the perspective of bits at the encoder, lower bit positions in the input bit sequence have better error protection.

After mapping, an input bit sequence v=[0,0,0,0,0,0,0,uₕ₁,0,0,0,uₕ₂,uₗ₁,uₗ₂,uₗ₃], is obtained. The input bit sequence v is multiplied by the polar generator matrix Gₚₒₗₐᵣ, to obtain the joint codeword cₚₒₗₐᵣ.

If a receiver is only interested in the high-priority packet, it can early terminate the decoding at bit index 11. This saves energy consumption and reduces latency.

Specifically, the two payloads are mapped to non-frozen bit positions by ascending bit index order. This can be described in pseudocode as follows, where s is an auxiliary variable, r is the number of groups, v is the value of a mapped bit, b is the value of an input bit (to be mapped), and Ci is the number of bits in the i-th group:

```
  group payload bits (CRC encoded) from different packets by descending priority,
resulting in r groups where group−o has bits b_{o,o}, b_{o,1} ,..., b_{o,Co-1}; group−1 has bits b_{1,0}, b_{1,1},, b_{1,C1-1};
...; and group−r has bits b_{r-1,o}, b_{r-1,1},..., b_{r-1,Cr-1}.
  the input bit sequence is denoted by b_{o,o}, b_{o,1},..., b_{o,Co-1}; b_{1,o}, b_{1,1},..., b_{1,C1-1}; ...;b_{r-1,o}, b_{r-1,1},,
b_{r-1,Cr-1}
  s=o;
  for i=o to r−1
    for c=o to Ci−1
      vₛ=b_{i,c};
      s=s+1;
    endfor
  endfor
```

The above groupwise priority-based mapping has two advantages. First, the first decoded group has a higher reliability. Second, thanks to sequential decoding, if the receiver only needs the high-priority packet, it can terminate decoding early to save energy and reduce latency.

### LDPC Codes

In some embodiments, the channel coding involves the use of a low density parity check (LDPC) code. In LDPC codes, reliability of a code bit is determined by many factors. The most significant factor is variable node (VN) degree. A code bit with a higher VN degree receives more information from adjacent check nodes (CN), and thus is statistically more reliable. These nodes also converge to a higher reliability much faster too.

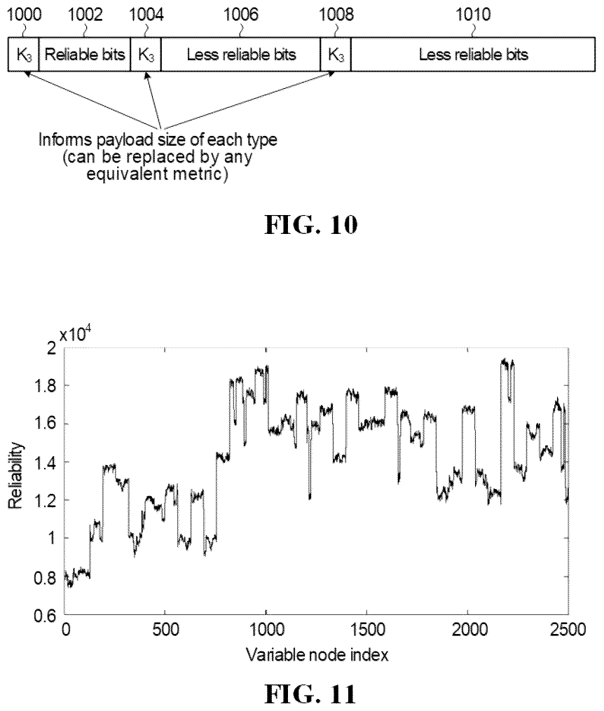

Thus, information bits with a higher VN degree are “better protected”. FIG. 11 shows an example of the different reliabilities of bit positions of a 5G NR LDPC code. This inherent unequal error protection (UEP) can be leveraged in the provided joint encoding method. Two specific example approaches are described below.

In a first example, when designing the parity-check matrix (or protograph, base graph), the columns are ordered by descending VN-degree order. When mapping payload bits, the payload bits are mapped sequentially as in the polar code example described previously. For example, the mapping order is [0,1,2,3,4,5] for the following LDPC matrix:

$$[ \begin{matrix}1 & 1 & 1 & 1 & 1 & 1 \\ 1 & 1 & 1 & 1 & 0 & 0 \\ 1 & 1 & 0 & 0 & 0 & 0\end{matrix} ]$$

Note that for protograph-based LDPC codes, a column may correspond to multiple bits. In this case it is possible to perform sequential mapping for the bits within a column. In a second example, the parity-check matrix (or protograph, base graph) is designed following existing methods, but payload bits are mapped by ascending column weight (or variable node degree) order.

For example, the mapping order is [0,1,4,5,2,3] for the following LDPC matrix:

$$[ \begin{matrix}1 & 1 & 1 & 1 & 1 & 1 \\ 1 & 1 & 0 & 0 & 1 & 1 \\ 1 & 1 & 0 & 0 & 0 & 0\end{matrix} ]$$

If a receiver is only interested in the high-priority packet, it can early terminate upon completing a pre-defined number of iterations. This saves energy consumption and reduces latency.

This can be described in pseudocode as follows:

```
  group payload bits (CRC encoded) from different packets by descending priority,
resulting in r groups where group-o has bits b_{o,o}, b_{o,1},..., b_{o,Co-1}; group-1 has bits b_{1,o}, b_{1,1},..., b_{1,C1-1};
...; and group-r has bits b_{r-1,0}, b_{r-1,1},..., b_{r-1,Cr-1}.
  the bit position sequence by ascending column weight order is w(o), w(o), ... , w(C),
where C=Co+ ... +Cr
  the input bit sequence (CRC encoded) is denoted by b_{o,o}, b_{o,1},..., b_{o,Co-1}; b_{1,o}, b_{1,1},...,
b_{1,C1-1}; ...;b_{r-1,o}, b_{r-1,1},..., b_{r-1,Cr-1}
  s=o;
  for i=o to r−1
    for c=o to Ci−1
      v_{w(s)}=b_{i,c};
      s=s+1;
    endfor
  endfor
```

Similar to polar codes, the above groupwise priority-based mapping has two advantages. First, the first decoded group has a higher reliability. Second, if the receiver only needs the high-priority packet, it can terminate decoding early to save energy and reduce latency. Here, use is made of the fact that the most reliable bits usually converge in the first few iterations under belief propagation (BP) decoding.

An overall procedure that employs the provided joint encoding can be summarized as follows:

Input sequence definition: Data packets of different priorities are optionally first protected by separate CRCs and mapped into a single information block (input bit sequence) according to their priority, and then encoded into a single codeword.

Definition of priority: Priority can be defined by different metrics, such as by reliability (target packet error rate), by packet type, or by source, target, or user.

Code-specific payload mapping: the mapping order from data packets to information block is code-specific:
For polar codes, map high-priority payload bits to information bits with smaller bit indices;
For LDPC codes, map high-priority payload bits to information bits with higher (variable node) degree.

Hybrid automatic repeat request (HARQ): If a receiver fails to decode its packet, a retransmission request is made for the entire jointly encoded packet, rather than an individual data packet.

Protocol design: a new MCS table can be used and explicit or implicit signaling, or indicator insertion, can inform the packet sizes in each code block.

In some embodiments, the described approach is used for physical layer wireless communications. But the approach can be adopted by upper layers of communications as well, as long as there are different packets (e.g. from different applications) of different priority.

In another embodiment, rather than combining payloads such that a high priority payload experiences better error protection than a low priority payload, the payloads are combined such that the high priority payload experiences improved latency compared to the low priority payload. In this case, bits with a higher latency priority may, for example, have less tolerance for increased latency than bits with a lower latency priority. In this case, the bits of the combined payload are mapped to and/or included in the input bit sequence for channel coding based on latency requirements. For example, in some embodiments, the first decoded bit positions (assuming a sequential decoder) are allocated for payload bits with a lower latency requirement. Note that low latency bit positions may not necessarily also have the greater error protection, but in some cases, the low latency bit positions may also have greater error protection. More generally, at least one bit position in the first set of payload bits has a lower decoding latency than the bit positions in the second set of payload bits. But for this change in mapping based on a latency requirement, all of the details of the previously described embodiments can be applied to this embodiment as well.

### Simulation Results and Observations

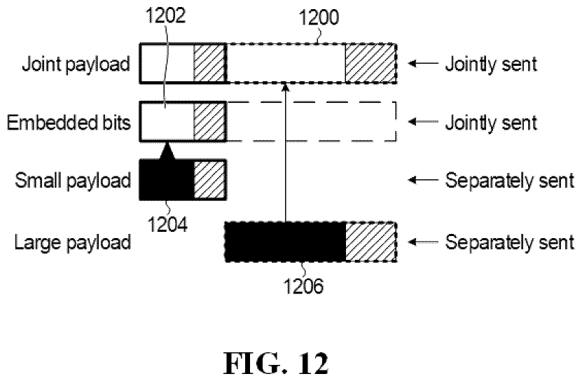

To better understand the disclosure, especially its benefits, extensive simulations were performed. In the simulated examples, there are two packets to be jointly decoded, and the high priority packet is referred to as the “small” packet (or embedded packet), and the low priority packet is referred to as the “large” packet. For each simulation, results were obtained for four different scenarios, depicted in FIG. 12. In a first scenario indicated at 1200, the block error rate for the jointly encoded payload is determined, referred to as BLER (joint). In a second scenario indicated at 1202, the block error rate for the high priority part of the jointly encoded payload, referred to below as BLER (embedded), is determined; this would be relevant for a receiver that can terminate decoding after decoding the first part of the payload. In a third scenario indicated at 1204, the block error rate for the small payload, separately sent, referred to below as BLER (small), is determined. In a fourth scenario indicated at 1206, the block error rate for the large payload, separately sent, referred to below as BLER (large), is determined.

For the simulations, the following setup is employed
Small payload: K1 bits; Small code length N1 bits
Large payload: K2 bits; Large code length N2 bits
Joint payload: K=K1+K2 bits; Joint code length: N=N1+N2 bits
N={256,1024}
Rate={¼,½,¾}
K1/K={ 1/16,⅛,¼}
Code construction: 5G NR Polar codes
CRC: 6-bit for small payload; 11-bit for large payload

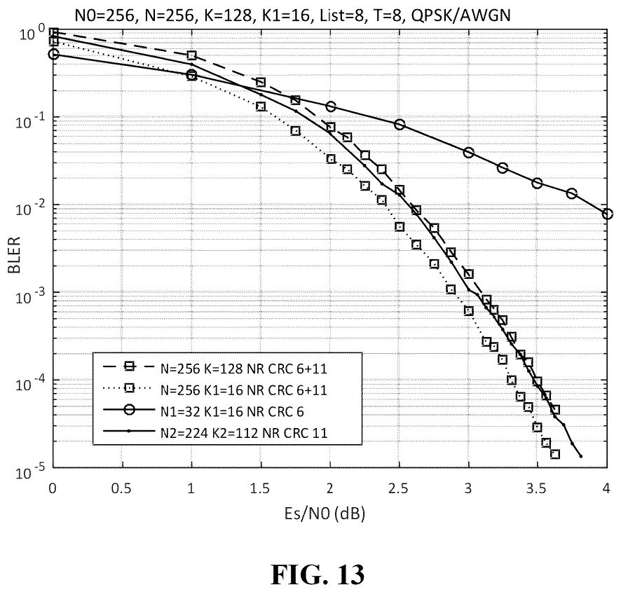

The results for a first case with K1=16, K2=112, K=128, N1=32, N2=224, N=256, Rate=½, are shown below in FIG. 13. As seen, the coding gain is significant.
BLER (embedded)=⅓BLER (joint)
BLER (embedded)= 1/200BLER (small)
BLER (embedded)<BLER (large)˜BLER (joint)

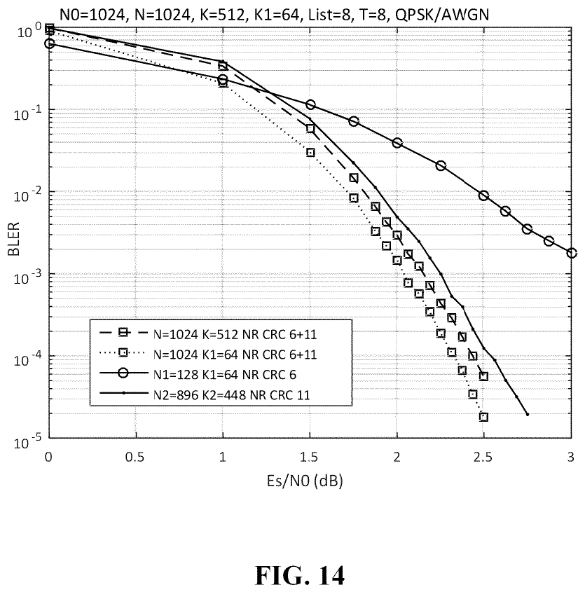

The results for another case with K1=64, K2=448, K=512, N1=128, N2=896, N=1024, are shown in FIG. 14. As seen, the coding gain is still significant.
BLER (embedded)=⅓BLER (joint)
BLER (embedded)= 1/100BLER (small)
BLER (embedded)<BLER (large)˜BLER (joint)

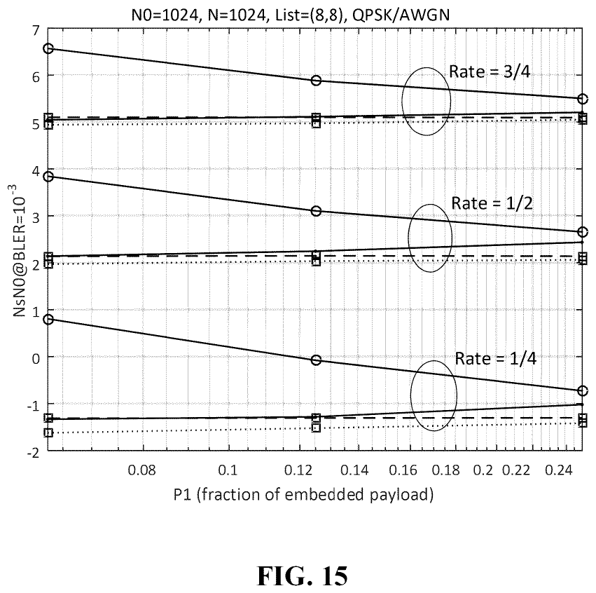

In FIG. 15, results for 27 cases with N=1024 but with different code rates and payload rates, are summarized and plotted in one single figure for better comparison, where
x-axis is the fraction of embedded payload with respect to the whole payload;
y-axis is the required SNR to achieve BLER=10⁻³, so the lower the better

As seen, the gain is higher when the fraction of embedded payload is small, and the gain is higher when both payloads are smaller.

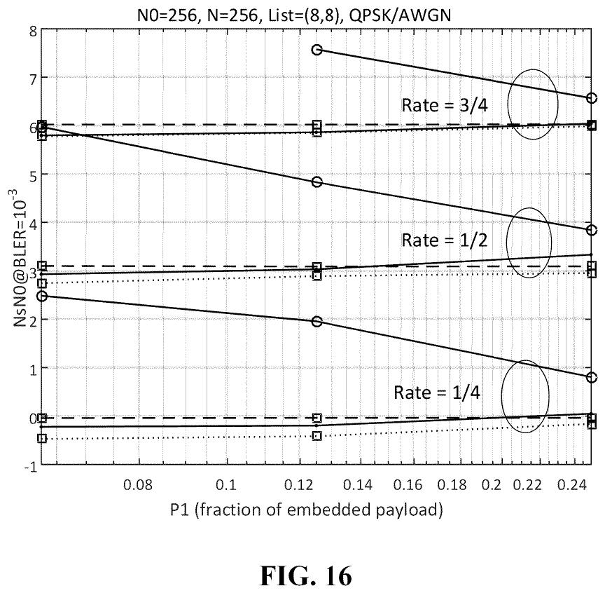

In FIG. 16, results for 27 cases with N=256 are also plotted and compared. Note that when the embedded payload is very small, a separate encoding will result in catastrophic performance, due to the negligible coding gain.

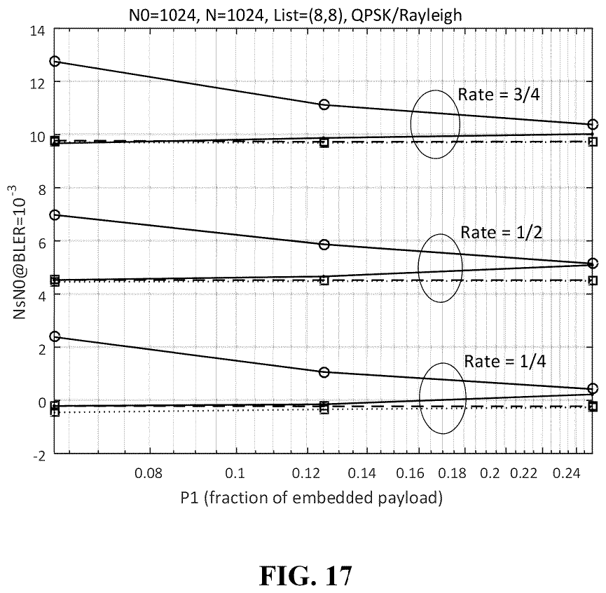

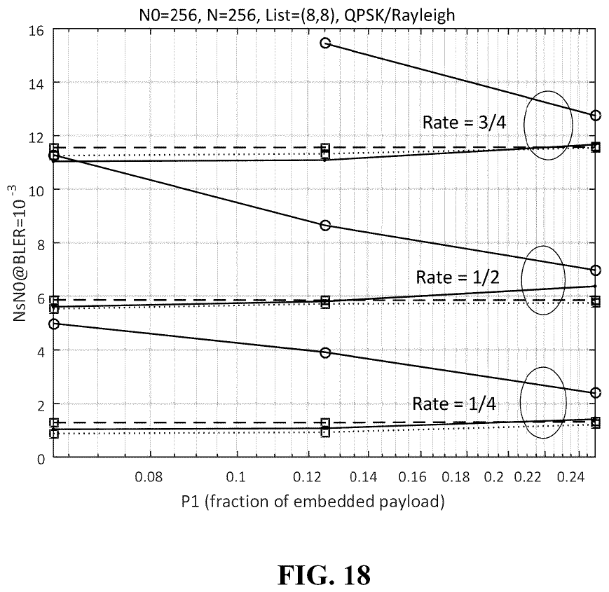

The results for FIGS. 15 and 16 are for additive white Gaussian noise (AWGN) channel. It is also worth noting that the scheme performs well under fading channels. Results corresponding to those of FIGS. 15 and 16, but under fading channel conditions, are summarized in FIGS. 17 and 18.

From the performance results, the following observations can be made:
embedded bits are self-decodable and are better protected;
embedded bits enjoy lower error rates than independent transmission;
embedded payload size that is small with respect to large payload size, will enjoy a large “joint coding” gain;
lower code rates and smaller code lengths yield a larger BLER difference between embedded bits and the joint codeword.

Numerous modifications and variations of the present disclosure are possible in light of the above teachings. It is therefore to be understood that within the scope of the appended claims, the disclosure may be practiced otherwise than as specifically described herein.

1. A method comprising:
obtaining a first set of payload bits having a first priority and a second set of payload bits having a second priority lower than the first priority;
encoding an input bit sequence using an error correction code to produce a codeword, the input bit sequence comprising the first set of payload bits and the second set of payload bits in bit positions within a combined payload of the input bit sequence, wherein at least one bit position of the first set of payload bits has a greater error protection than second bit positions of the second set of payload bits within the combined payload; and
outputting the codeword.

2. The method of claim 1, wherein the error correction code is a Polar code, the first set of payload bits is included in first bit positions with smaller bit indices of the input bit sequence, and the second set of payload bits is included in the second bit positions with larger bit indices of the input bit sequence.

3. The method of claim 1, wherein the error correction code is a Low Density Parity Check (LDPC) code, the first set of payload bits is included in first bit positions with higher variable node degree of the LDPC code, and the second set of payload bits is included in the second bit positions with smaller variable node degree of the LDPC code.

4. The method of claim 1, further comprising:
encoding the first set of payload bits using an outer code to produce a first set of encoded payload bits, wherein the input bit sequence comprises the first set of encoded payload bits and the second set of payload bits in the bit positions within the combined payload.

5. The method of claim 1, further comprising:
including in the combined payload an indication of how many bits are in the first set of bits and how many bits are in the second set of bits.

6. A method comprising:
obtaining a first set of payload bits having a first priority and a second set of payload bits having a second priority lower than the first priority;
encoding an input bit sequence using an error correction code to produce a codeword, the input bit sequence comprising the first set of payload bits and the second set of payload bits in bit positions within a combined payload of the input bit sequence, wherein at least one bit position of the first set of payload bits has a lower decoding latency than second bit positions of the second set of payload bits within the combined payload; and
outputting the codeword.

7. The method of claim 6, wherein the error correction code is a Polar code, the first set of payload bits is included in first bit positions with smaller bit indices of the input bit sequence, and the second set of payload bits is included in the second bit positions with larger bit indices of the input bit sequence.

8. The method of claim 6, wherein the error correction code is a Low Density Parity Check (LDPC) code, the first set of payload bits is included in first bit positions with higher variable node degree of the LDPC code, and the second set of payload bits is included in the second bit positions with smaller variable node degree of the LDPC code.

9. The method of claim 6, further comprising:
encoding the first set of payload bits using an outer code to produce a first set of encoded payload bits, wherein the input bit sequence comprises the first set of encoded payload bits and the second set of payload bits in the bit positions within the combined payload.

10. The method of claim 6, further comprising:
including in the combined payload an indication of how many bits are in the first set of bits and how many bits are in the second set of bits.

11. An apparatus comprising:
an encoder input for obtaining a first set of payload bits having a first priority and a second set of payload bits having a second priority lower than the first priority;
an encoder for encoding an input bit sequence using an error correction code to produce a codeword, the input bit sequence comprising the first set of payload bits and the second set of payload bits in bit positions within a combined payload of the input bit sequence, wherein at least one bit position of the first set of payload bits has a greater error protection than second bit positions of the second set of payload bits within the combined payload; and
an encoder output for outputting the codeword.

12. The apparatus of claim 11, wherein the error correction code is a Polar code and the first set of payload bits is included in first bit positions with smaller bit indices of the input bit sequence, and the second set of payload bits is included in the second bit positions with larger bit indices of the input bit sequence.

13. The apparatus of claim 11, wherein the error correction code is a Low Density Parity Check (LDPC) code, the first set of payload bits is included in first bit positions with higher variable node degree of the LDPC code, and the second set of payload bits is included in the second bit positions with smaller variable node degree of the LDPC code.

14. The apparatus of claim 11, wherein the encoder is further for:
encoding the first set of payload bits using an outer code to produce a first set of encoded payload bits, wherein the input bit sequence comprises the first set of encoded payload bits and the second set of payload bits in the bit positions within the combined payload.

15. The apparatus of claim 11, wherein the encoder is further for:
including in the combined payload an indication of how many bits are in the first set of bits and how many bits are in the second set of bits.

16. An apparatus comprising:
an encoder input for obtaining a first set of payload bits having a first priority and a second set of payload bits having a second priority lower than the first priority;
an encoder for encoding an input bit sequence using an error correction code to produce a codeword, the input bit sequence comprising the first set of payload bits and the second set of payload bits in bit positions within a combined payload of the input bit sequence, wherein at least one bit position of the first set of payload bits has a lower decoding latency than second bit positions of the second set of payload bits within the combined payload; and
an encoder output for outputting the codeword.

17. The apparatus of claim 16, wherein the error correction code is a Polar code, the first set of payload bits is included in first bit positions with smaller bit indices of the input bit sequence, and the second set of payload bits is included in the second bit positions with larger bit indices of the input bit sequence.

18. The apparatus of claim 16, wherein the error correction code is a Low Density Parity Check (LDPC) code, the first set of payload bits is included in first bit positions with higher variable node degree of the LDPC code, and the second set of payload bits is included in the second bit positions with smaller variable node degree of the LDPC code.

19. The apparatus of claim 16, wherein the encoder is further for:
encoding the first set of payload bits using an outer code to produce a first set of encoded payload bits, wherein the input bit sequence comprises the first set of encoded payload bits and the second set of payload bits in the bit positions within the combined payload.

20. The apparatus of claim 16, wherein the encoder is further for:
including in the combined payload an indication of how many bits are in the first set of bits and how many bits are in the second set of bits.
